(19) United States
(12) Patent Application Publication
(10) Pub. No.: US 2025/0381638 A1
(43) Pub. Date: Dec. 18, 2025

(54) WORKPIECE PROCESSING METHOD

(71) Applicant: DISCO CORPORATION, Tokyo (JP)

(72) Inventor: Kohta NAGATA, Tokyo (JP)

(21) Appl. No.: 19/207,639

(22) Filed: May 14, 2025

(30) Foreign Application Priority Data
Jun. 12, 2024 (JP) 2024-095493

(51) Int. Cl. B24B 7/22; B24B 41/06; H01L 21/304

(52) U.S. Cl. CPC B24B 7/228; B24B 41/068; H01L 21/304

(57) ABSTRACT

A novel technology is proposed for a technology of configuring a laminated body in which a workpiece is laminated on a supporting substrate and then thinning the workpiece. A workpiece processing method includes an adhesive material supply step of laying an adhesive material on a supporting substrate, a facing step of causing a workpiece to face the adhesive material, a laminated body forming step of pressing the adhesive material with the workpiece to integrate the workpiece and the supporting substrate together and form a laminated body, a supporting substrate grinding step of grinding and planarizing an exposed surface of the supporting substrate of the laminated body, and a thinning step of, after the supporting substrate grinding step, thinning the workpiece to a predetermined thickness by grinding an exposed surface of the workpiece of the laminated body.

### BACKGROUND OF THE INVENTION

### 1. Field of the Invention

The present invention relates to a processing method for a sheet-shaped object, and particularly relates to a processing method of thinning the sheet-shaped object to a predetermined thickness by grinding the sheet-shaped object.

### 2. Description of the Related Art

Conventionally, as disclosed in, e.g., JP 2004-207606 A, when a sheet-shaped object, such as a semiconductor wafer, is to be subjected to thinning processing as a workpiece, as thinning proceeds, a rigidity of the workpiece significantly decreases, and consequently a crack, warping, or the like occurs during transportation or the processing. To prevent this problem, a process is known in which the workpiece is laminated on a rigid supporting substrate (support substrate) via an adhesive material to form a laminated body, and the workpiece of the laminated body is ground.

In addition, with regard to such a grinding method, as disclosed in, e.g., JP 2011-119578 A, it is known that a workpiece is fixed to a top surface of a supporting substrate via a liquid resin serving as an adhesive material, and ground to a predetermined thickness.

### SUMMARY OF THE INVENTION

When such processing as disclosed in JP 2011-119578 A is to be performed, it is required that a thickness variation after a workpiece, an adhesive material, and a supporting substrate are laminated together is small, i.e., a high degree of planarity is achieved. If the degree of planarity is low (the thickness variation is large), the low degree of planarity may cause a crack or chipping during grinding. Moreover, a limit of thinning also depends on the degree of planarity, i.e., there may be cases where, due to the low degree of planarity, the thinning cannot be performed to an intended thickness.

In such a device configuration as disclosed in JP 2011-119578 A, for example, accuracy after the lamination (resin thickness variation) is highly dependent on a degree of parallelism due to component accuracy of each constituent member of a device or an installation error. Specifically, a degree of parallelism between a stage (upper base or holding means) that suction-holds a workpiece and a stage (surface plate) on which a supporting substrate and a liquid resin are to be laid can be increased by adjustment, but intended accuracy cannot be reached depending on a component tolerance or the installation error, and consequently a thickness variation of the laminated resin determines the limit of thinning when the workpiece of the laminated body is ground. This results in a problem that the workpiece may not reach an intended thickness or, even when the intended thickness is reached, a thickness variation of the workpiece is large to result in a poor quality after processing.

In view of the foregoing problems, the present invention proposes a novel technology for a technology of configuring a laminated body in which a workpiece is laminated on a supporting substrate and then thinning the workpiece.

The foregoing is the problems to be solved by the present invention, and a means for solving the problems will be described next.

In accordance with an aspect of the present invention, there is provided a workpiece processing method including: an adhesive material supply step of laying an adhesive material on a supporting substrate; a facing step of causing a workpiece to face the adhesive material; a laminated body forming step of pressing the adhesive material with the workpiece to integrate the workpiece and the supporting substrate together and form a laminated body; a supporting substrate grinding step of grinding and planarizing an exposed surface of the supporting substrate of the laminated body; and a thinning step of, after the supporting substrate grinding step, thinning the workpiece to a predetermined thickness by grinding an exposed surface of the workpiece of the laminated body.

In accordance with another aspect of the present invention, the adhesive material is a liquid resin which is hardened by an external stimulus.

In accordance with still another aspect of the present invention, the supporting substrate is made of silicon, glass, or a resin.

In accordance with yet another aspect of the present invention, in the supporting substrate grinding step, an amount of the grinding of the supporting substrate is larger than a thickness variation of the laminated body.

In accordance with still another aspect of the present invention, in each of the supporting substrate grinding step and the thinning step, the grinding is performed using the same grinding stone.

In accordance with yet another aspect of the present invention, each of the supporting substrate and the workpiece is configured to include the same material.

The present invention achieves the following effects.

In other words, according to the aspect of the present invention, even when, e.g., a high degree of parallelism cannot be ensured in a constituent member of a device for forming a laminated body due to the component tolerance or installation error of various components, it is possible to hold a laminated body such that an exposed surface of a workpiece thereof is horizontal. As a result, it is possible to evenly grind a back surface of the workpiece parallel to a horizontal surface to make the workpiece thinner and increase a limit of thinning, i.e., it is possible to process the workpiece thinner. In addition, by eliminating a thickness variation, it is possible to improve a quality of a chip finally manufactured.

### BRIEF DESCRIPTION OF THE DRAWINGS

FIG. 1 is a diagram illustrating an overview of a configuration of a pressing device;

FIG. 2A is a diagram illustrating a supporting substrate placement step;

FIG. 2B is a diagram illustrating an adhesive material supply step;

FIG. 3A is a diagram illustrating a facing step;

FIG. 3B is a diagram illustrating a laminated body formation step;

FIG. 4A is a diagram illustrating application of ultraviolet light;

FIG. 4B is a diagram illustrating a formed laminated body;

FIG. 5A is a diagram illustrating a supporting substrate grinding step;

FIG. 5B is a diagram illustrating grinding of a supporting substrate;

FIG. 6A is a diagram illustrating a thickness variation of the laminated body;

FIG. 6B is a diagram illustrating occurrence of a level difference;

FIG. 7A is a diagram illustrating an amount of grinding;

FIG. 7B is a diagram illustrating a state after grinding of the supporting substrate;

FIG. 8A is a diagram illustrating a thinning step;

FIG. 8B is a diagram illustrating grinding of a workpiece;

FIG. 9A is a diagram illustrating no occurrence of a thickness variation according to the present invention; and

FIG. 9B is a diagram illustrating occurrence of a thickness variation in a comparative example not according to the present invention.

### DESCRIPTION OF THE PREFERRED EMBODIMENTS

Referring to the drawings, a description will be given hereinbelow of an embodiment of the present invention.

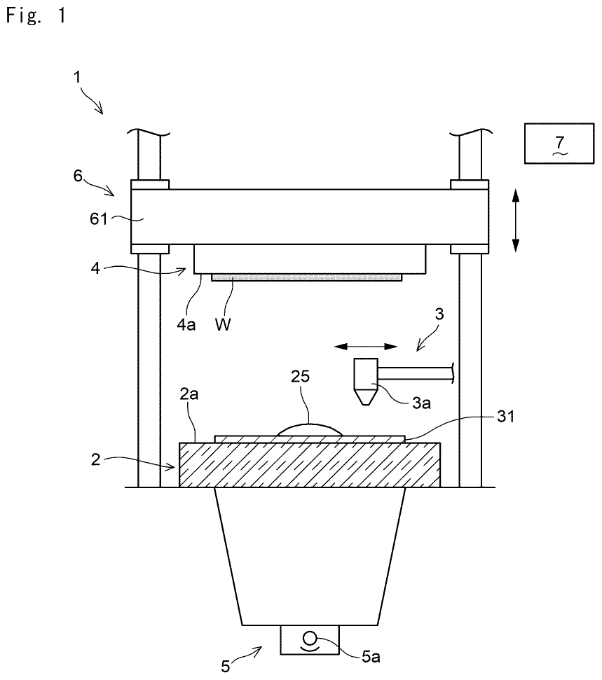

FIG. 1 is a diagram illustrating an overview of a configuration of a pressing device as an example of a device for forming a laminated body. FIG. 1 illustrates a pressing device 1 in which a wafer W as a workpiece is caused to face a resin 25 as an adhesive material laid on an upper surface of a supporting substrate 31.

The pressing device 1 is configured to have a table 2, a holding means 4 (holding pad), a lifting means 6, an ultraviolet light applying means 5, a resin supply means 3, and a control device 7 for controlling various operating units.

A table 2 is configured to have a horizontal upper surface 2a and transmit ultraviolet light, and is formed of a transparent member made of, e.g., glass or the like. In the horizontal upper surface 2a, a suction groove is formed to lead to a suction source not shown and, by generating a negative pressure on the upper surface 2a, the upper surface 2a is configured as a suction-holding surface.

The holding means 4 is disposed above the horizontal upper surface 2a of the table 2, while a suction groove is formed in a horizontal lower surface 4a thereof to lead to a suction source not shown and, by generating a negative pressure on the lower surface 4a, the lower surface 4a is configured as the suction-holding surface. By the lower surface 4a, an upper surface of the wafer W as the workpiece is suction-held to expose a lower surface thereof. The suction-held upper surface of the wafer W is a surface scheduled to be ground later and serves as a back surface on which, e.g., no device is to be formed, while the lower surface of the wafer W serves as a top surface (device surface) on which a device is to be formed. It may also be possible that no device is formed on either of the both surfaces of the wafer W, and the workpiece may be not only a semiconductor device wafer, but also any of various sheet-shaped workpieces made of a ceramic, glass, and the like, or the workpiece may be a laminated wafer obtained by bonding a plurality of wafers together.

The holding means 4 is fixed to a lower surface of a lifting base 61 of the lifting means 6 to rise and fall with the lifting base 61. The lifting means 6 has an actuator not shown and operates the actuator to raise and lower the lifting base 61.

The ultraviolet light applying means 5 has a light source 5a disposed below the table 2 to emit ultraviolet light. Specifically, as will be described later, the ultraviolet light penetrates the table 2 and the supporting substrate 31 to harden the resin 25.

The resin supply means 3 has a supply nozzle 3a for supplying the liquid resin 25 to the upper surface of the supporting substrate 31 placed on the table 2. The supply nozzle 3a is configured to be movable by the actuator not shown, and is located at a supply position that locates the supply nozzle 3a at a center position of the table 2 and at a retracted position away from the table 2. The supply nozzle 3a is connected to a resin supply source not shown to be able to supply a predetermined amount of the resin 25 to the upper surface of the supporting substrate 31.

Next, a description will be given of a processing method using the pressing device configured as described above.

### Supporting Substrate Placing Step

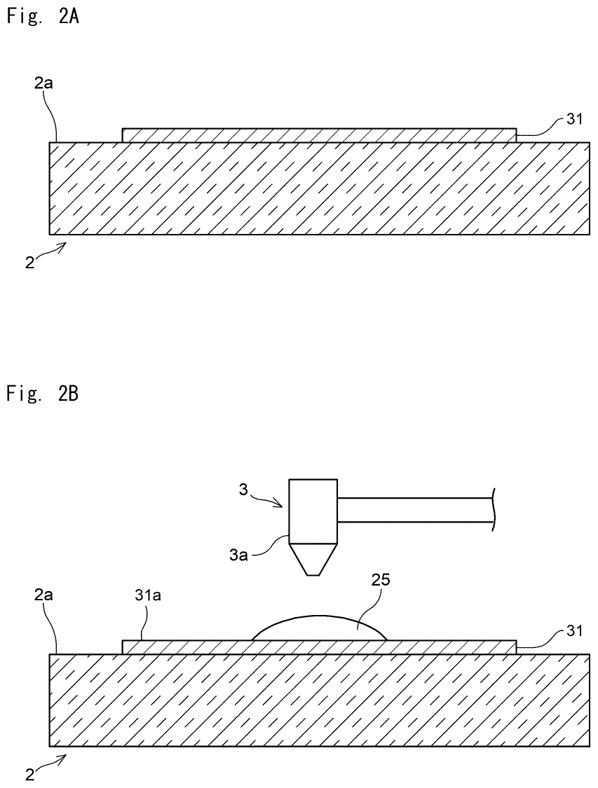

As illustrated in FIG. 2A, a supporting substrate placing step is a step of placing the supporting substrate 31 on the table 2.

Specifically, the supporting substrate 31 is placed so as to align a center portion of the supporting substrate 31 with a substantially center portion of the horizontal upper surface 2a of the table 2. The supporting substrate 31 has a TTV (Total Thickness Variation) of preferably not more than 3 μm, or more preferably not more than 1 μm.

A material of the supporting substrate 31 can be not only silicon, but also, e.g., glass or a resin. A shape of the supporting substrate 31 can be not only a disc shape, but also, e.g., a rectangular sheet shape.

### Adhesive Material Supply Step

As illustrated in FIG. 2B, an adhesive material supply step is a step of laying the resin 25 as the adhesive material on the supporting substrate 31.

Specifically, above a substantially center portion of an upper surface 31a of the supporting substrate 31, the supply nozzle 3a is located, and the resin 25 is dropped from the supply nozzle 3a to be supplied in a predetermined amount to the upper surface 31a. For example, the resin 25 is an ultraviolet-curing resin and, e.g., “Resilock” (registered trademark) manufactured by DISCO Corporation is used. After being hardened, the resin 25 transmits the ultraviolet light.

### Facing Step

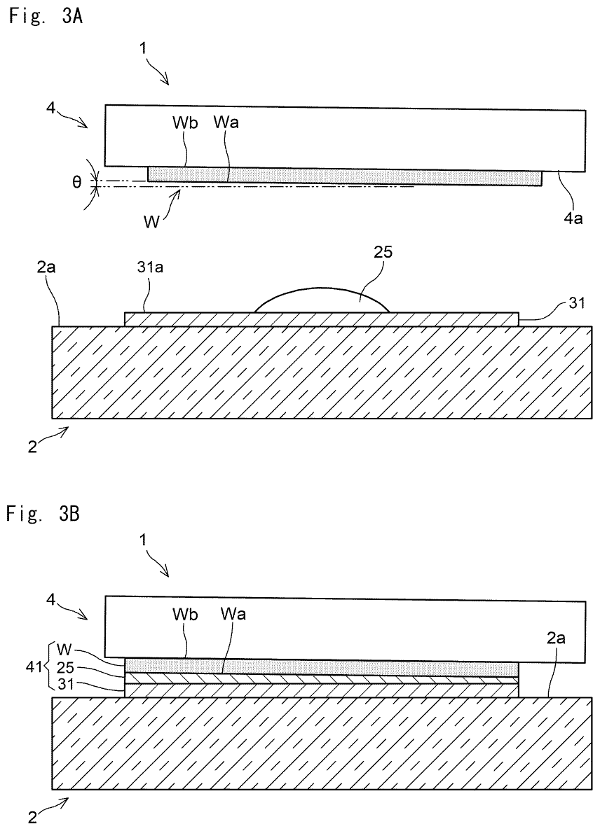

As illustrated in FIG. 3A, a facing step is a step of causing the wafer W as the workpiece to face the resin 25 as the adhesive material.

Specifically, a negative pressure is generated on a lower surface 4a of the holding means 4 to suction-hold a back surface Wb of the wafer W. For example, the wafer W is a semiconductor device wafer with a device to be formed on a top surface Wa thereof exposed to face downward or the like, but is not particularly limited.

In the example in FIG. 3A, it is illustrated that, as a result of tilting of the holding means 4, the top surface Wa of the wafer W is inclined at an angle θ such that a right side thereof is lower.

### Laminated Body Forming Step

As illustrated in FIG. 3B, a laminated body forming step is a step of pressing the adhesive material (resin 25) with the workpiece (wafer W) to integrate the workpiece (wafer W) and the supporting substrate 31 together and form a laminated body 41.

Specifically, first, the supply nozzle 3a (FIG. 1) is retracted so as to be away from the position below the holding means 4, and the wafer W held by the holding means 4 is lowered by the lifting means 6 (FIG. 1). When the lower surface (top surface Wa) of the wafer W reaches the resin 25, the resin 25 is spread with no gap between the wafer W and the supporting substrate 31. Note that as a result of coverage of the top surface Wa of the wafer W with the resin 25, the device formed on the top surface Wa is covered with the resin 25.

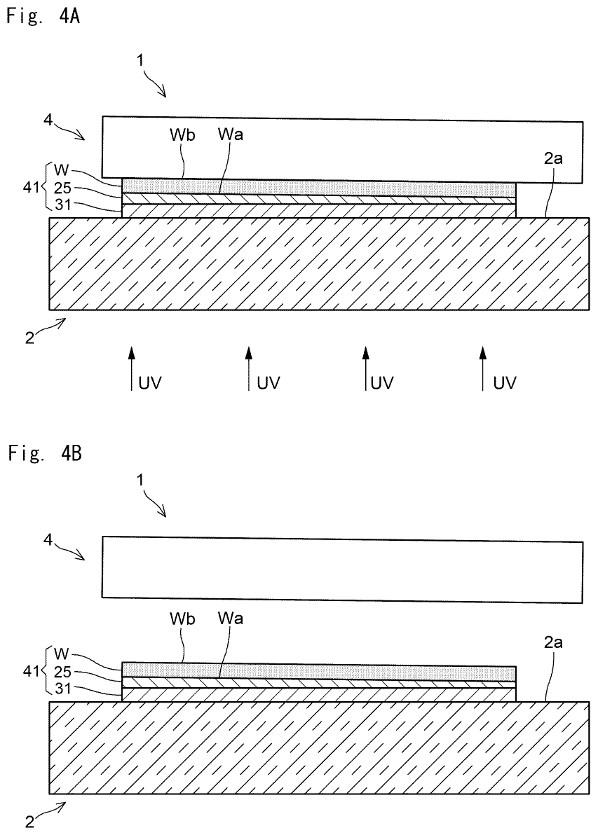

Then, as illustrated in FIG. 4A, ultraviolet light UV is applied from below by the ultraviolet light applying means 5 (FIG. 1) to the resin 25 via the table 2 and the supporting substrate 31 to harden the resin 25. Thus, the resin 25 is hardened to form a resin layer, while the wafer W and the supporting substrate 31 are bonded together via the resin layer made of the resin 25 to be integrated.

Then, as illustrated in FIG. 4B, the wafer W suction-held by the holding means 4 is released therefrom, while the holding means 4 is upwardly retracted to result in a state where the laminated body 41 is placed on the table 2.

Note that, in the present embodiment, as a means for the external stimulus for hardening the resin 25, the application of the ultraviolet light is used, but another example of the external stimulus is heat, and it can be considered to use a thermo-setting resin as the resin.

When the application of the ultraviolet light is used as the means for the external stimulus, it is necessary to form the supporting substrate 31 as a transmission member made of glass, a resin, or the like to transmit the ultraviolet light. Meanwhile, when heat is used as the means for the external stimulus, there is no need to transmit the ultraviolet light, and therefore, e.g., a plate made of the same material as that of the wafer W, such as silicon, can be used. For the resin 25, a UV-setting resin (delayed curing) in which a curing reaction proceeds with a time lag after the application of the ultraviolet light can also be used.

### Supporting Substrate Grinding Step

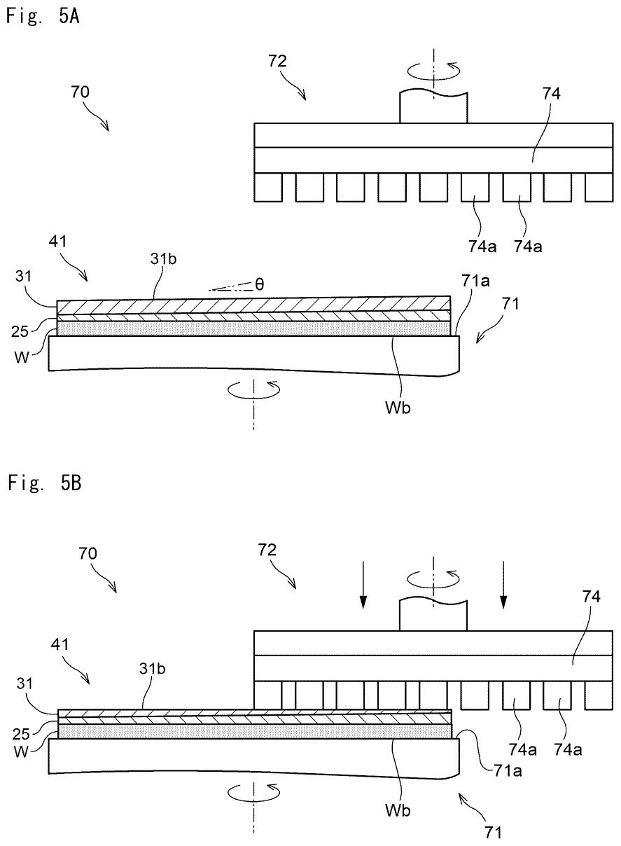

As illustrated in FIGS. 5A and 5B, a supporting substrate grinding step is a step of grinding and planarizing an exposed surface 31b of the supporting substrate 31 of the laminated body 41.

Specifically, as illustrated in FIG. 5A, first, the back surface Wb of the wafer W of the laminated body 41 is held on a holding surface 71a of a chuck table 71 of a grinding device 70 to expose upwardly the back surface (exposed surface 31b) of the supporting substrate 31 opposite to the wafer W. Note that, at this time, the exposed surface 31b is inclined at the angle θ corresponding to the inclination of the holding means 4 described above.

The grinding device 70 is configured to mainly have the chuck table 71 and a grinding unit 72, and grinds the exposed surface 31b of the supporting substrate 31 and the back surface Wb of the wafer W, as will be described later. On the holding surface 71a of the chuck table 71, a suction groove not shown is formed and, by generating a negative pressure in the suction groove, the laminated body 41 is suction-held on the holding surface 71a. The chuck table 71 is configured to be rotated by a rotation mechanism not shown.

The grinding unit 72 has a grinding wheel 74 on which a plurality of grinding stones 74a are annularly arranged to be spaced apart from each other. The grinding wheel 74 is rotated at a predetermined speed by the rotation mechanism not shown, while being fed at a predetermined speed by a grinding feeding mechanism not shown.

Then, as illustrated in FIG. 5B, the grinding unit 72 serving as a grinding means of the grinding device grinds and planarizes the exposed surface 31b of the supporting substrate 31.

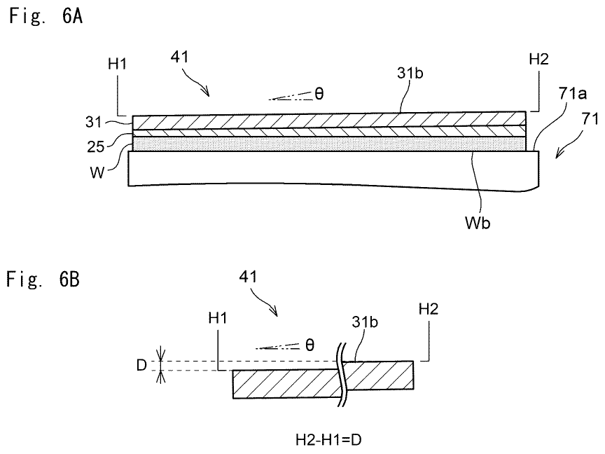

The grinding is performed such that an amount of the grinding of the supporting substrate is larger than a thickness variation of the laminated body. Specifically, as illustrated in, e.g., FIGS. 6A and 6B, when the inclination at the angle θ of the exposed surface 31b causes a level difference D between a lowest position H1 and a highest position H2 in a state where the laminated body 41 is held on the holding surface 71a, the level difference D is assumed to be the variation.

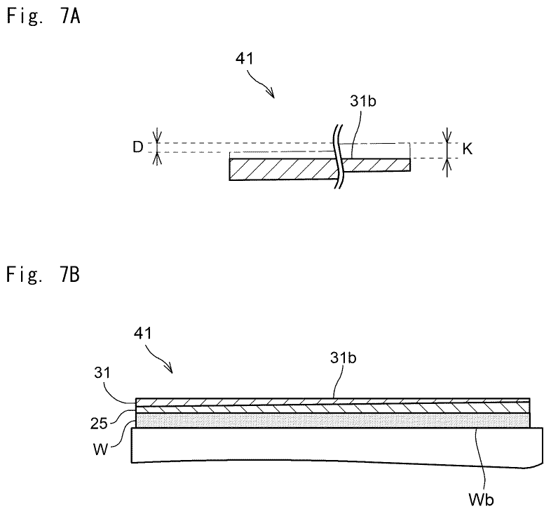

In this case, as illustrated in FIG. 7A, by performing the grinding such that a grinding amount K is larger than the level difference D, it is possible to horizontal the exposed surface 31b of the supporting substrate 31 after being ground, as illustrated in FIG. 7B.

By using the supporting substrate 31 having a sufficient thickness, even after the grinding is performed in the grinding amount K, the supporting substrate 31 is left to be able to prevent the resin 25 from being exposed. Note that, after the supporting substrate 31 is thinned by the grinding, a portion of the resin 25 may also be exposed.

### Thinning Step

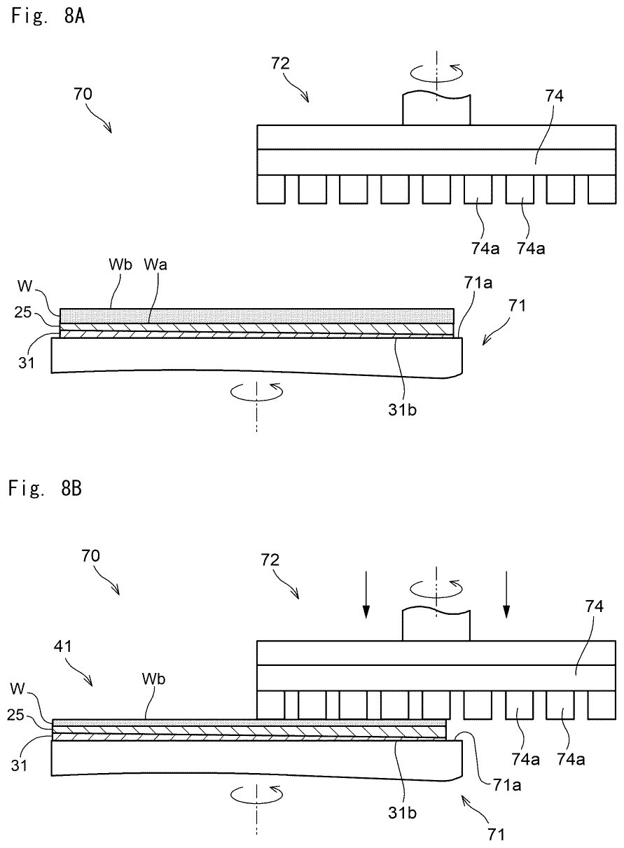

As illustrated in FIGS. 8A and 8B, a thinning step is a step of grinding the exposed surface (back surface Wb) of the workpiece (wafer W) of the laminated body 41 after the supporting substrate grinding step to thin the wafer W to an intended thickness.

Specifically, as illustrated in FIG. 7B, first, the laminated body 41 after being subjected to the supporting substrate grinding step is removed from the chuck table 71, while the front and back of the laminated body 41 are reversed and, as illustrated in FIG. 8A, the exposed surface 31b of the supporting substrate 31 of the laminated body 41 is held on the holding surface 71a of the chuck table 71. Thus, the back surface Wb of the wafer W opposite to the supporting substrate 31 is brought into an upwardly exposed state.

In this state, the back surface Wb of the wafer W is parallel to the exposed surface 31b of the supporting substrate 31 after being ground and parallel to the holding surface 71a of the chuck table 71, and therefore the back surface Wb of the wafer W is in a horizontal state with no inclination.

Note that, as the grinding device 70 to be used in the thinning step, the grinding device used in the supporting substrate grinding step can be used. In this case, in each of the supporting substrate grinding step and the thinning step, the grinding can be performed using the same grinding stones 74a, and the two steps can be performed in the one device. Meanwhile, when, e.g., each of the wafer W and the supporting member 31 includes the same material, the common grinding stones 74a can be used. Note that the grinding device 70 to be used in the thinning step may also be another grinding device other than that used in the supporting substrate grinding step.

Then, as illustrated in FIG. 8B, the back surface Wb of the wafer W is ground with the grinding unit 72 serving as a grinding means of the grinding device to thin the wafer W to a predetermined thickness (finishing thickness).

According to the foregoing embodiment, as illustrated in, e.g., FIG. 3A, the lower surface 4a of the holding means 4, which is a component of a constituent member of the device (pressing device 1) for forming the laminated body, is inclined and, even when the lower surface 4a is not parallel to the horizontal upper surface 2a of the table 2 or when a high degree of parallelism cannot be ensured due to the component tolerance or installation error of various components, it is possible to hold the laminated body 41 during the grinding such that the exposed surface (back surface Wb) of the wafer W thereof is horizontal, as illustrated in FIG. 8A.

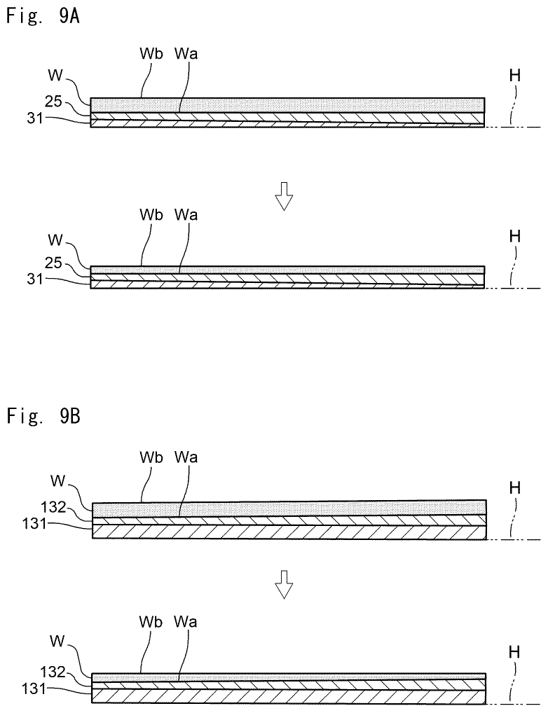

Thus, as illustrated in FIG. 9A, it is possible to evenly thin the back surface Wb of the wafer W parallel to a horizontal surface H during the grinding and increase a limit of thinning, i.e., it is possible to process the wafer W thinner. In addition, it is possible to obtain the thinned wafer W with no thickness variation. By eliminating a thickness variation, it is possible to increase a quality of a chip finally manufactured.

Meanwhile, FIG. 9B illustrates a comparative example not according to the present embodiment, and illustrates a case where the wafer W as the workpiece is integrated with a supporting substrate 131 via a resin layer 132. It is illustrated that, since the supporting substrate 131 is not ground, the back surface Wb of the wafer W is inclined and, consequently, during grinding, the wafer W is not evenly thinned to result in a thickness variation. It is concerned that the presence of such a thickness variation degrades the quality of the chip finally manufactured.

### REFERENCE SIGNS LIST

1 Pressing device
2 Table
2a Upper surface
3 Resin supply means
3a Supply nozzle
4 Holding means
4a Lower surface
5 Ultraviolet light applying means
5a Light source
6 Lifting means
7 Control device
25 Resin
31 Supporting substrate
31a Upper surface
31b Exposed surface
41 Laminated body
61 Lifting base
70 Grinding device
71 Chuck table
71a Holding surface
72 Grinding unit
74 Grinding wheel
74a Grinding stone
D Level difference
H Horizontal surface
H1 Lowest position
H2 Highest position
K Grinding amount
UV Ultraviolet light
W Wafer
Wa Top surface
5 Wb Back surface
θ Angle

What is claimed is:

1. A workpiece processing method comprising:
an adhesive material supply step of laying an adhesive material on a supporting substrate;
a facing step of causing a workpiece to face the adhesive material;
a laminated body forming step of pressing the adhesive material with the workpiece to integrate the workpiece and the supporting substrate together and form a laminated body;
a supporting substrate grinding step of grinding and planarizing an exposed surface of the supporting substrate of the laminated body; and
a thinning step of, after the supporting substrate grinding step, thinning the workpiece to a predetermined thickness by grinding an exposed surface of the workpiece of the laminated body.

2. The workpiece processing method of claim 1, wherein the adhesive material is a liquid resin which is hardened by an external stimulus.

3. The workpiece processing method of claim 1, wherein the supporting substrate is made of silicon, glass, or a resin.

4. The workpiece processing method of claim 1, wherein, in the supporting substrate grinding step, an amount of the grinding of the supporting substrate is larger than a thickness variation of the laminated body.

5. The workpiece processing method of claim 1, wherein, in each of the supporting substrate grinding step and the thinning step, the grinding is performed using the same grinding stone.

6. The workpiece processing method of claim 1, wherein each of the supporting substrate and the workpiece is configured to include the same material.
